(19) United States
(12) Patent Application Publication
(10) Pub. No.: US 2014/0216929 A1
(43) Pub. Date: Aug. 7, 2014

(54) DOPED ZINC TARGET

(71) Applicant: Applied Materials, Inc., Santa Clara, CA (US)

(72) Inventors: Aki HOSOKAWA, Sunnyvale, CA (US); John M. WHITE, Hayward, CA (US); Dong-Kil YIM, Santa Maria, CA (US)

(21) Appl. No.: 14/169,203

(22) Filed: Jan. 31, 2014

Related U.S. Application Data
(60) Provisional application No. 61/767,971, filed on Feb. 22, 2013.
(60) Provisional application No. 61/759,569, filed on Feb. 1, 2013.

(51) Int. Cl. C23C 14/34

(52) U.S. Cl. CPC C23C 14/3414
USPC 204/298.13

(57) ABSTRACT

The present invention generally relates to a sputtering target comprised of zinc and a dopant. Zinc is utilized for metal oxide semiconductor materials, such as IGZO, zinc oxide and zinc oxynitride. The zinc may be delivered by sputtering a zinc target in a desired atmosphere. If a pure zinc sputtering target is used, a stable film cannot be produced unless mobility is sacrificed to below 10 cm²/V-s. By adding a dopant, such as gallium, not only can a stable film be deposited, but the film will have a mobility of greater than 30 cm²/V-s. The dopant can be incorporated directly into the zinc or as a separate sputtering target directly adjacent the zinc sputtering target.

### CROSS-REFERENCE TO RELATED APPLICATIONS

This application claims benefit of U.S. Provisional Patent Application Ser. No. 61/759,569 (APPM/20414L), filed Feb. 1, 2013, and U.S. Provisional Patent Application Ser. No. 61/767,971 (APPM/20414L02), filed Feb. 22, 2013, both of which are herein incorporated by reference.

### BACKGROUND OF THE INVENTION

1. Field of the Invention

Embodiments of the present invention generally relate to a doped zinc sputtering target.

2. Description of the Related Art

Indium-gallium-zinc oxide (IGZO) is a famous semiconductor material that has a high mobility. IGZO is one of the metal oxide semiconductor materials that are generally believed to be semiconductor material for the next generation of thin film transistors (TFTs). Mobilities of between about 30 cm²/V-s and about 40 cm²/V-s have been obtained for IGZO. However, in production, IGZO is not very stable. In order to increase the stability for IGZO, the mobility needs to be sacrificed such that the mobility is less than 10 cm²/V-s for stable IGZO films in TFTs.

IGZO is not the only metal oxide semiconductor material that is considered for the next generation TFTs. Zinc oxide and zinc oxynitride are considered to be viable candidates for metal oxide semiconductor TFTs too. Zinc oxide and zinc oxynitride both have higher mobility than IGZO, but suffer from the same stability issues that IGZO experiences. In order to achieve a stable zinc based semiconductor film, mobility needs to be sacrificed.

Therefore, there is a need in the art to stably form zinc based semiconductor material while maintaining a high mobility.

### SUMMARY OF THE INVENTION

The present invention generally relates to a sputtering target comprised of zinc and a dopant. Zinc is utilized for metal oxide semiconductor materials, such as IGZO, zinc oxide and zinc oxynitride. The zinc may be delivered by sputtering a zinc target in a desired atmosphere. If a pure zinc sputtering target is used, a stable film cannot be produced unless mobility is sacrificed to below 10 cm²/V-s. By adding a dopant, such as gallium, not only can a stable film be deposited, but the film will have a mobility of greater than 30 cm²/V-s. The dopant can be incorporated directly into the zinc or as a separate sputtering target directly adjacent the zinc sputtering target.

In one embodiment, a sputtering target assembly comprises a backing tube; and a sputtering target coupled to the backing tube and comprising zinc and one or more dopants that are dispersed within the zinc.

In another embodiment, a sputtering target assembly comprises a backing tube; a first sputtering target coupled to the backing tube and comprising zinc; and a second sputtering target coupled to the backing tube, disposed adjacent the first sputtering target, and comprising one or more items are selected from the group consisting of gallium, indium, In₂O₃, GaO, GaN, GeO, GeO₂, tin, tin oxide, ruthenium, RuO₂, hafnium, titanium, TiO₂, TiN, silicon, SiOₓ, boron, B₂O₃ and combinations thereof.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional illustration of a physical vapor deposition (PVD) apparatus according to one embodiment.

FIG. 2A is a schematic illustration of a sputtering target according to one embodiment.

FIG. 2B is a schematic illustration of a sputtering target according to another embodiment.

FIG. 2C is a schematic illustration of a sputtering target according to another embodiment.

FIGS. 3A and 3B are schematic illustrations of a target being sprayed onto a backing tube and backing plate respectively according to embodiments of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally relates to a sputtering target comprised of zinc and a dopant. Zinc is utilized for metal oxide semiconductor materials, such as IGZO, zinc oxide and zinc oxynitride. The zinc may be delivered by sputtering a zinc target in a desired atmosphere. If a pure zinc sputtering target is used, a stable film cannot be produced unless mobility is sacrificed to below 10 cm²/V-s. By adding a dopant, such as gallium, not only can a stable film be deposited, but the film will have a mobility of greater than 30 cm²/V-s. The dopant can be incorporated directly into the zinc or as a separate sputtering target directly adjacent the zinc sputtering target.

Description herein will be made with reference to a PVD apparatus. A suitable PVD apparatus that may be utilized to practice the invention is available from AKT PIVOT PVD apparatus or an AKT New Aristo PVD apparatus available from AKT America, Inc., a subsidiary of Applied Materials, Inc., Santa Clara, Calif. It is to be understood that the embodiment discussed herein have utility in PVD apparatus sold by other manufacturers as well.

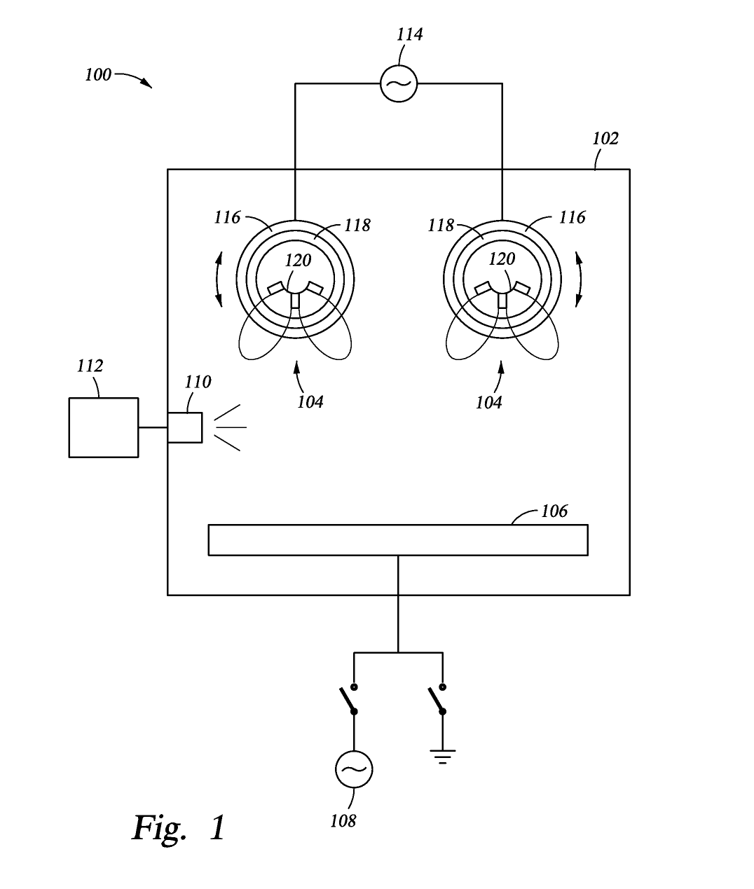

FIG. 1 is a schematic cross-sectional illustration of a PVD apparatus 100 according to one embodiment. The apparatus 100 includes a chamber body 102 having one or more sputtering target assemblies 104 therein. The sputtering target assemblies 104 are disposed within the chamber body 102 opposite a substrate 106. It is to be understood that while the sputtering target assemblies 104 are shown to be disposed above the substrate 106, the sputtering target assemblies 104 and substrate 106 may have other orientations. For example, the substrate 106 may be vertical as may be the sputtering target assemblies 104. As shown in FIG. 1, the substrate 106 may be biased by being coupled to a power supply 108, may be grounded by being coupled to ground or may be electrically floating. Processing gas, such as an inert gas or a reactive gas, may be introduced to the chamber body 102 through one or more gas inlet ports 110 that are coupled to one or more gas sources 112.

The sputtering target assemblies 104 may also be coupled to a power source 114. The power source 114 may comprise a DC power source or an AC power source. It is to be understood that while description will be made with reference to rotary, cylindrical sputtering targets, the embodiments disclosed herein are equally applicable to planar sputtering targets. Each sputtering target assembly 104 comprises a sputtering target 116 bonded a backing tube (or plate in the case of a planar sputtering target) 118. A magnetron 120 may be disposed behind the backing tube 118. For a rotary, cylindrical sputtering target assembly 104, the target 116 (and tube 118) may rotate as shown by the arrows while the magnetron generates magnetic fields. Material is sputtered off of the sputtering target 116 and reacts with a reactive gas and deposits as a layer on the substrate 106. In the case of zinc oxynitride, the zinc sputtering target reacts with both oxygen and nitrogen to form zinc oxynitride on the substrate.

As discussed above, a pure zinc target may produce a semiconductor film having a high mobility, but the film will not be stable. Applicants have discovered that by including a dopant in an amount of between about 2 percent to about 30 percent, a stable film may be produced, and the film may have a mobility of greater than 30 cm²/V-s. Therefore, the sputtering target 116 may comprise one or more dopants.

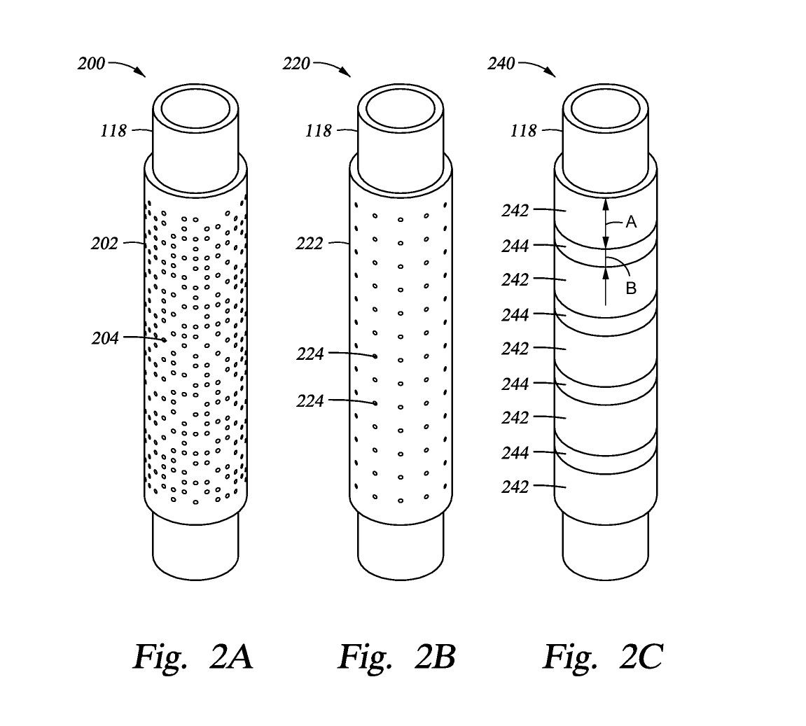

FIG. 2A is a schematic illustration of a sputtering target 200 according to one embodiment. As shown in FIG. 2A, the sputtering target 202 is coupled to the backing tube 118. In the embodiment of FIG. 2A, the zinc sputtering target 202 has numerous dopant particles randomly dispersed therein. The one or more dopants may be selected from gallium, indium, In₂O₃, GaO, GaN, GeO, GeO₂, tin, tin oxide, ruthenium, RuO₂, hafnium, titanium, TiO₂, TiN, silicon, SiOₓ (where x is 1 or 2), boron, B₂O₃ and combinations thereof. The dopants may have an average particle size of between about 1 nanometer and about 5 microns and be present in an amount of between about 2 atomic percent to about 30 atomic percent. The presence of a dopant not only maintains the zinc mobility, but also increases the stability of the zinc so that the resulting semiconductor film can have a mobility of greater than 30 cm²/V-s and also be stable. The dopant particles may be spray deposited along with the zinc onto the backing tube directly or onto a support tube that slides over the backing tube 118. In order to manufacture the sprayed target, the zinc and the dopants are sprayed simultaneously onto the backing tube 118 or support tube. When using gallium as the dopant, gallium oxide is sprayed because gallium melts at about 30 degrees Celsius.

FIG. 2B is a schematic illustration of a sputtering target 220 according to another embodiment. In the embodiment shown in FIG. 2B, the dopant particles 224 are uniformly dispersed within the zinc target 222. The dopant particles, such as gallium oxide or gallium nitride, may be casted with zinc and formed by a casting process such as cast iron is formed. The dopant may be selected from gallium, indium, In₂O₃, GaO, GaN, GeO, GeO₂, tin, tin oxide, ruthenium, RuO₂, hafnium, titanium, TiO₂, TiN, silicon, SiOₓ (where x is 1 or 2), boron, B₂O₃ and combinations thereof. The dopants may have an average particle size of between about 1 nanometer and about 5 microns and be present in an amount of between about 2 atomic percent to about 30 atomic percent. The presence of a dopant not only maintains the zinc mobility, but also increases the stability of the zinc so that the resulting semiconductor film can have a mobility of greater than 30 cm²/V-s and also be stable.

FIG. 2C is a schematic illustration of a sputtering target 240 according to another embodiment. In the embodiment shown in FIG. 2C, a zinc target 242 is disposed on the backing tube 118 adjacent a dopant target 244. The zinc target 242 has a length shown by arrow “A” while the dopant target 244 has a length shown by arrow “B”. The length of the zinc target 242 to the length of the dopant target 244 is between about 1:5:1 to about 2.3:1, such as about 2:1. Because the target 240 will be disposed about 200 to about 250 mm from the substrate 106 during processing, the target material will generally mix uniformly before landing on the substrate 106 which will lead to not only a mobility of greater than 30 cm²/V-s, but also a stable film. When the zinc target 242 is about 2:1 in length relative to the dopant target 244, the target 240 will be the equivalent to a 30 atomic percent doped sputtering target.

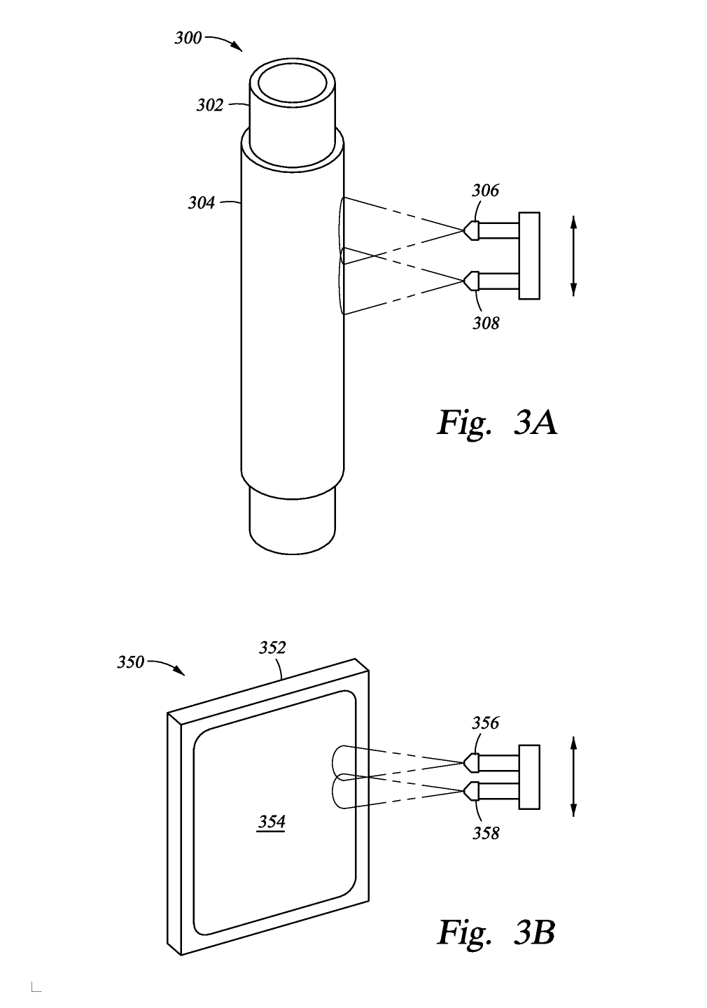

FIGS. 3A and 3B are schematic illustrations of a target being sprayed onto a backing tube and backing plate respectively according to embodiments of the invention. As shown in FIG. 3A, a sputtering target 304 may be formed on a backing tube 302 to create a target assembly 300. The zinc may be plasma sprayed from a source 306 and the dopant may be plasma sprayed from a source 308. The sources 306, 308 may move along the length of the desired sputtering target 304 as shown by arrows “A”. Similarly, for a planar target assembly 350, zinc may be plasma sprayed from a first source 356 and the dopant may be plasma sprayed from a second source 358 onto a backing plate 352 to form a target 354. The sources 356, 358 may move along the desired area of the sputtering target 354 as shown by arrows “B”.

By doping a zinc target, either by intermixing dopant particles with the zinc or by placing dopant targets adjacent the zinc target, a high mobility zinc containing metal oxide may be deposited that is also stable.

While the foregoing is directed to embodiments of the present invention, other and further embodiments of the invention may be devised without departing from the basic scope thereof, and the scope thereof is determined by the claims that follow.

1. A sputtering target assembly, comprising:
a backing tube; and
a sputtering target coupled to the backing tube and comprising zinc and one or more dopants that are dispersed within the zinc.

2. The assembly of claim 1, wherein the one or more dopants are selected from the group consisting of gallium, indium, In₂O₃, GaO, GaN, GeO, GeO₂, tin, tin oxide, ruthenium, RuO₂, hafnium, titanium, TiO₂, TiN, silicon, SiOₓ where x is 1 or 2, boron, B₂O₃ and combinations thereof.

3. The assembly of claim 2, wherein the one or more dopants are present in an amount of between about 2 atomic percent to about 30 atomic percent.

4. The assembly of claim 3, wherein the one or more dopants are dispersed within the zinc and have an average particle size of between about 1 nanometer and about 5 microns.

5. The assembly of claim 4, wherein the one or more dopants are casted with the zinc.

6. The assembly of claim 4, wherein the one or more dopants and the zinc are sprayed onto the backing tube.

7. The assembly of claim 1, wherein the one or more dopants are present in an amount of between about 2 atomic percent to about 30 atomic percent.

8. The assembly of claim 7, wherein the one or more dopants are dispersed within the zinc and have an average particle size of between about 1 nanometer and about 5 microns.

9. The assembly of claim 8, wherein the one or more dopants are casted with the zinc.

10. The assembly of claim 8, wherein the one or more dopants and the zinc are sprayed onto the backing tube.

11. The assembly of claim 1, wherein the one or more dopants are dispersed within the zinc and have an average particle size of between about 1 nanometer and about 5 microns.

12. The assembly of claim 11, wherein the one or more dopants are casted with the zinc.

13. A sputtering target assembly, comprising:
a backing tube;
a first sputtering target coupled to the backing tube and comprising zinc; and
a second sputtering target coupled to the backing tube, disposed adjacent the first sputtering target, and comprising one or more items are selected from the group consisting of gallium, indium, In₂O₃, GaO, GaN, GeO, GeO₂, tin, tin oxide, ruthenium, RuO₂, hafnium, titanium, TiO₂, TiN, silicon, SiOₓ where x is 1 or 2, boron, B₂O₃ and combinations thereof.

14. The assembly of claim 13, wherein the first sputtering target has a first length, the second sputtering target has a second length and wherein the first length is greater than the second length.

15. The assembly of claim 14, further comprising a third sputtering target coupled to the backing tube, disposed adjacent the second sputtering target such that the second sputtering target is disposed between the first sputtering target and the third sputtering target, and comprises zinc.

16. The assembly of claim 15, wherein the first length is about double the second length.
